(19) United States
(12) Patent Application Publication
(10) Pub. No.: US 2005/0133882 A1
(43) Pub. Date: Jun. 23, 2005

(54) Integrated circuit fuse and method of fabrication

(75) Inventor: John M. Young, Austin, TX (US)

Correspondence Address: WOLF GREENFIELD & SACKS, PC;FEDERAL RESERVE PLAZA, 600 ATLANTIC AVENUE, BOSTON, MA, 02210-2211, US

(73) Assignee: Analog Devices, Inc., Norwood, MA (US)

(21) Appl. No.: 11/015,890

(22) Filed: Dec. 17, 2004

Related U.S. Application Data
(60) Provisional application No. 60/530,146, filed on Dec. 17, 2003.

(51) Int. Cl. H01L 27/14

(52) U.S. Cl. 257/529

(57) ABSTRACT

An integrated circuit fuse includes P-type and N-type regions in a substrate, the P-type and N-type regions abutting at a junction, a conductive layer on the P-type and N-type regions, and circuit connections to the conductive layer for applying sufficient electrical energy to open the conductive layer over the junction in response to a fuse program signal. A method for fabricating an integrated circuit fuse is also provided.

### CROSS REFERENCE TO RELATED APPLICATION

This application claims priority based on provisional application Ser. No. 60/530,146, filed Dec. 17, 2003, which is hereby incorporated by reference in its entirety.

### FIELD OF THE INVENTION

This invention relates to integrated circuit manufacturing and, more particularly, to integrated circuit fuses and methods for making integrated circuit fuses.

### BACKGROUND OF THE INVENTION

Many integrated circuit designs include large on-chip memory arrays. One example is a digital signal processor. In order to improve yield rates, the memory arrays may be fabricated with redundant rows and columns to permit repair after fabrication. Single bit failures may be repaired by replacing the column or row containing the failure. The repair may be achieved through the use of integrated circuit fuses which disable the faulty column or row and which enable a spare column or row of the memory array.

Integrated circuit fuses may also be used to program various features of a chip, such as a chip ID and/or circuit parameters. Fuse trimming of analog integrated circuits is described, for example, in U.S. Pat. No. 5,384,727, issued Jan. 24, 1995 to Moyal et al., and U.S. Pat. No. 5,412,594, issued May 2, 1995 to Moyal et al.

A chip may include multiple integrated circuit fuses. Such integrated circuit fuses should have extremely small dimensions, should blow reliably and should have two distinct logic states.

In one prior art approach, a metal fuse is programmed by using laser energy to interrupt metal continuity. The cost of chip repair is often 10% of the total manufacturing cost, but this cost has been determined to be acceptable due to the large yield loss when repair is not employed.

In another prior art approach, a fuse includes a polysilicon link having a metal surface layer. When the fuse is to be programmed, an electrical current is passed through the metal layer, causing metal migration and thermal rupture. The resistance typically changes from 2 ohms per square to 30 ohms per square, roughly an order of magnitude change. Energy application is continued until the polysilicon thermally ruptures. The additional energy required for thermal rupture of the polysilicon is quite large. Also, the resistance in the open condition is in the 10K ohm range. Thus, the fuse is not totally open. Furthermore, the resistance may decrease over time. Polysilicon fuses are described, for example, in U.S. Pat. No. 5,973,977, issued Oct. 26, 1999 to Boyd et al. and by D. Anand et al. in “An On-Chip Self-Repair Calculation and Fusing Methodology,” IEEE Design & Test of Computers, September-October 2003, pages 67-75.

All of the prior art integrated circuit fuses have had one or more disadvantages. Accordingly, there is a need for improved integrated circuit fuses and methods of making integrated circuit fuses.

### SUMMARY OF THE INVENTION

According to a first aspect of the invention, an integrated circuit fuse is provided. The integrated circuit fuse comprises P-type and N-type regions in a substrate, the P-type and N-type regions abutting at a junction, a conductive layer on the P-type and N-type regions, and circuit connections to the conductive layer for applying sufficient electrical energy to open the conductive layer over the junction in response to a fuse program signal.

According to a second aspect of the invention, a method is provided for fabricating an integrated circuit fuse. The method comprises forming in a substrate P-type and N-type regions which abut at a junction, forming a conductive layer on the P-type and N-type regions, and connecting the conductive layer to an electrical energy source for applying sufficient electrical energy to open the conductive layer over the junction in response to a fuse program signal.

### BRIEF DESCRIPTION OF THE DRAWINGS

For a better understanding of the present invention, reference is made to the accompanying drawings, which are incorporated herein by reference and in which:

FIG. 1 is a simplified cross-sectional diagram of an integrated circuit fuse in accordance with a first embodiment of the invention;

FIG. 2 is a top view of the integrated circuit fuse of FIG. 1;

FIG. 3 is a schematic diagram that illustrates an equivalent circuit of the integrated circuit fuse of FIGS. 1 and 2;

FIG. 4 is a top view of an integrated circuit fuse in accordance with a second embodiment of the invention; and

FIG. 5 is a cross-sectional diagram of the integrated circuit fuse of FIG. 4.

### DETAILED DESCRIPTION

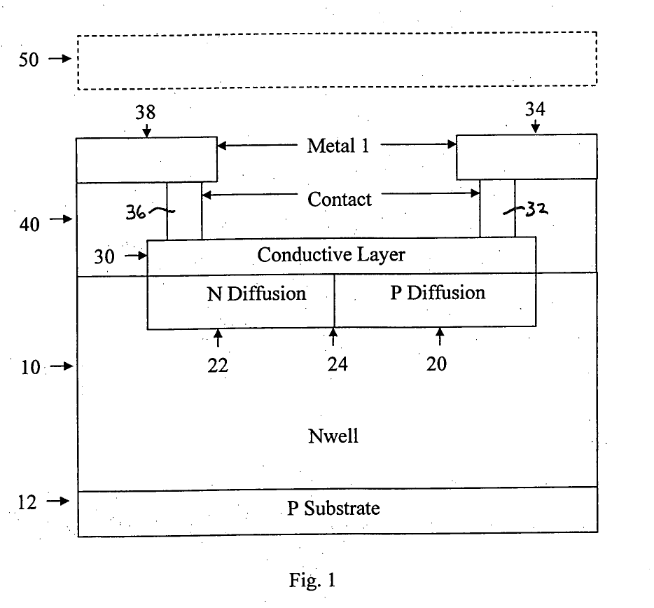

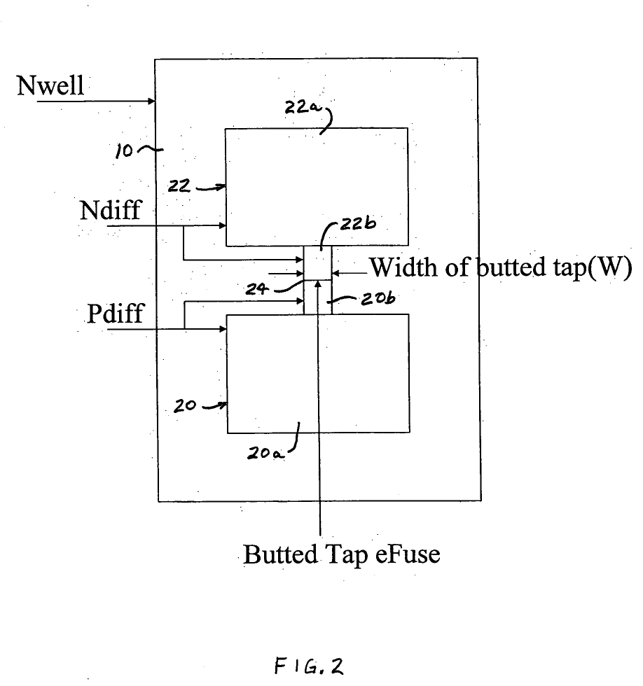

An integrated circuit fuse in accordance with a first embodiment of the invention is shown in FIGS. 1 and 2. FIG. 1 is a cross-sectional view, and FIG. 2 is a top view. An N-well 10 is formed in a P-type substrate 12. A P-type region 20 and an N-type region 22 are formed in N-well 10. P-type region 20 and N-type region 22 abut at a junction 24. P-type region 20 and N-type region 22, also referred to as a P-type diffusion and an N-type diffusion, respectively, may be formed by ion implantation of suitable dopant ions and subsequent annealing to produce diffusion of the dopant ions to form a semiconductor diode.

A conductive layer 30 is formed over P-type region 20 and N-type region 22 and, in particular, covers junction 24. Conductive layer 30 may be a metal or a metal silicide, such as a metal silicide formed according-to a self-aligned silicide process. Conductive layer 30 above P-type region 20 is connected by a contact 32 to a metal interconnect line 34. Conductive layer 30 above N-type region 22 is connected by a contact 36 to a metal interconnect line 38. Metal interconnect lines 34 and 38 may be part of a patterned metal layer separated from substrate 12 by an insulating layer 40. In actual practice, metal interconnect line 34 may be connected by multiple contacts 32 to conductive layer 30 and metal interconnect line 38 may be connected by multiple contacts 36 to conductive layer 30 in order to increase current-carrying capability.

As shown in FIG. 2, P-type region 20 may include a relatively large area contact portion 20a and a relatively narrow junction portion 20b. Similarly, N-type region 22 may include a relatively large area contact portion 22a and a relatively narrow junction portion 22b. Junction portions 20b and 22b abut at junction 24 and define a width, W, of junction 24.

According to the self-aligned silicide process, a metal silicide is formed on P-type region 20 and N-type region 22 and does not form outside these regions. Accordingly, conductive layer 30 (FIG. 1) has a relatively large area over contact portions 20a and 22a and is relatively narrow over junction portions 20b and 22b. This configuration permits multiple contacts to conductive layer 30 over contact portions 20a and 22a. In addition, conductive layer 30 is relatively narrow over junction 24 to facilitate rupture of the conductive layer 30 when the fuse is programmed, as described below. When an electrical current is passed through conductive layer 30, the current density is greatest in the narrow portions over junction 24, thereby tending to rupture conductive layer 30 over junction 24.

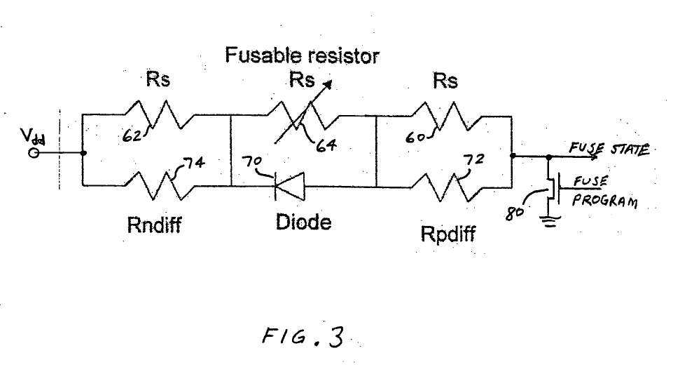

An equivalent circuit of the integrated circuit fuse of FIGS. 1 and 2 is shown in FIG. 3. Resistors 60 and 62 represent the resistance of conductive layer 30 over P-type region 20 and N-type region 22, respectively. A variable resistor 64 represents the resistance of conductive layer 30 over junction 24. A diode 70 corresponds to the diode at junction 24 between P-type region 20 and N-type region 22. Resistors 72 and 74 represent the bulk resistance of P-type region 20 and N-type region 22, respectively. As further shown in FIG. 3, resistors 62 and 74 may be connected to a supply voltage V_{dd}, and resistors 60 and 72 may be connected to a transistor switch 80. Transistor switch 80 may connect resistors 60 and 72 to a reference voltage, such as ground, in response to a fuse program signal. Referring again to FIG. 1, supply voltage V_{dd} may be connected to metal interconnect line 38, and transistor switch 80 may be connected to metal interconnect line 34.

In use, the integrated circuit fuse of FIGS. 1-3 is fabricated in a closed state and may be irreversibly programmed to an open state. In the closed state, electrical current flows from metal interconnect line 38 through conductive layer 30 to metal interconnect line 34. In the open state, the fuse has a high electrical resistance between metal interconnect line 38 and metal interconnect line 34 when diode 70 is reverse-biased. The fuse of FIGS. 1-3 is programmed by passing an electrical current through conductive layer 30 sufficient to cause metal migration and rupture. This may be achieved by applying the fuse program signal to transistor switch 80, which thereby connects conductive layer 30 and P-type region 20 to ground so that electrical current passes through conductive layer 30. Because conductive layer 30 is relatively narrow over junction 24, as shown in FIG. 2, the metal ruptures above junction 24. This leaves P-type region 20 and N-type region 22, which function as reverse-biased diode 70 (FIG. 3) having a high resistance, typically in the 100 k ohm range.

An example of integrated circuit fuse in accordance with an embodiment of the invention is now described. The P-type region 20 may be formed by implantation of impurity atoms with a dose in a range of 10¹⁵ to 10²⁰ atoms per cubic centimeter (cm). The N-type region 22 may be formed by implantation of impurity atoms having a dose in a range of 10¹⁵ to 10²⁰ atoms per cubic cm. The P-type region 20 and the N-type region 22 may have depths on the order of 200 Angstroms, and the width, W, of junction 24 may be in a range of 0.1 to 0.5 micrometer (μm). Conductive layer 30 may be tungsten having a thickness in a range of 10 to 100 Angstroms. Other suitable materials for conductive layer 30 include titanium, platinum and palladium. It will be understood that these parameters are given by way of example only and are not limiting as to the scope of the invention.

An optional feature of the invention is shown in FIG. 1. A thermal shield 50 may be positioned above junction 24. The thermal shield may be a metal layer, such as, for example, a patterned area of a metal interconnect layer of the integrated circuit. The shield 50 helps to contain the heat in a region local to the fuse to promote rupture at a lower energy. The shield 50 also serves to protect upper levels of the integrated circuit from the heat of the rupturing fuse.

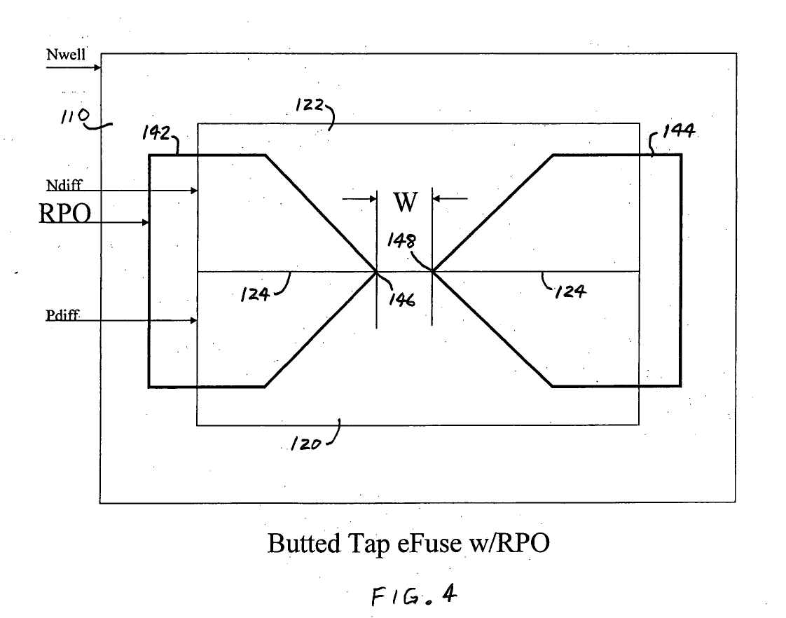

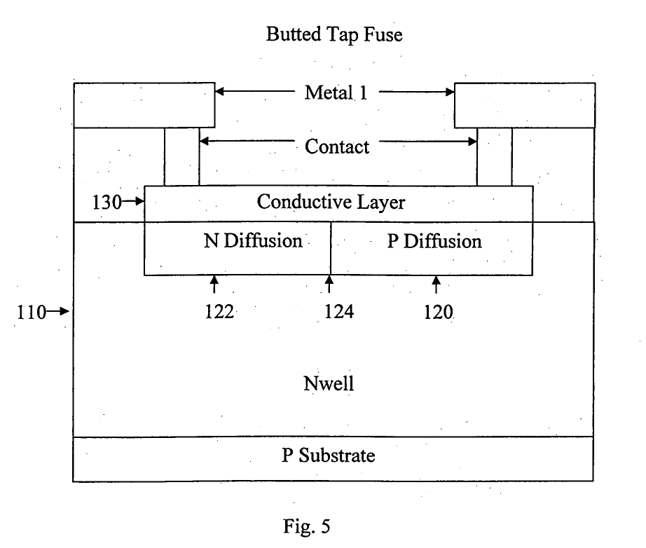

An integrated circuit fuse in accordance with a second embodiment of the invention is shown in FIGS. 4 and 5. FIG. 4 is a top view, and FIG. 5 is a cross-sectional view. A P-type region 120 and an N-type region 122 are formed in an N-well 110. P-type region 120 and N-type 122 abut at a junction 124. In contrast to the embodiment of FIGS. 1-3, P-type region 120 and N-type 122 do not include relatively narrow junction portions. Instead, P-type region 120 and N-type region 122 abut along their full widths to provide a robust PN junction.

In the embodiment of FIGS. 4 and 5, the size and shape of a conductive layer 130 which covers P-type region 120 and N-type region 122 is defined by a patterned masking layer. A masking layer known as RPO may be used for patterning of a silicide conductive layer 130. The masking layer is represented in FIG. 4 by mask segments 140 and 142 which define areas that are not covered by conductive layer 130. As shown in FIG. 4, mask segment 142 is tapered to a peak 146 above junction 124, and mask segment 144 is tapered to a peak 148 above junction 124. The area outside mask segments 142 and 144 defines the area covered by conductive layer 130. Thus, a spacing between peaks 146 and 148 defines the width, W, of conductive layer 130 over junction 124. The taper of mask segments 142 and 144 ensures that conductive layer 130 has its smallest width, W, over junction 124. As a result, when an electrical current is passed through conductive layer 130, the current density is greatest in the narrow region over junction 124, and conductive layer 130 tends to rupture above junction 124.

It will be understood that the size and shape of conductive layer 130 can be controlled by controlling the size and shape of mask segments 142 and 144. Thus for example, the spacing between peaks 146 and 148 and the tapers of mask segments 142 and 144 may be varied. Furthermore, the tapers may be linear or non-linear.

It will be understood that a practical integrated circuit may include any number of integrated circuit fuses of the type shown and described herein. The fuses are combined with other circuitry to provide a desired functionality.

While there have been shown and described what are at present considered the preferred embodiments of the present invention, it will be obvious to those skilled in the art that various changes and modifications may be made therein without departing from the scope of the invention as defined by the appended claims.

1. An integrated circuit fuse, comprising:
P-type and n-type regions in a substrate, said p-type and n-type regions abutting at a junction;
a conductive layer on the p-type and n-type junctions; and
circuit connections to the conductive layer for applying sufficient electrical energy to open the conductive layer at the junction in response to a fuse program signal.

2. An integrated circuit fuse as defined in claim 1, wherein the P-type and N-type regions comprise P-type and N-type diffusions, respectively.

3. An integrated circuit fuse as defined in claim 1, wherein the P-type and N-type regions are formed in an N-well in the substrate.

4. An integrated circuit fuse as defined in claim 1, wherein the conductive layer comprises a silicide layer.

5. An integrated circuit fuse as defined in claim 1, wherein the conductive layer comprises a metal.

6. An integrated circuit fuse as defined in claim 1, wherein the conductive layer comprises tungsten.

7. An integrated circuit fuse as defined in claim 1, wherein the conductive layer is shaped so as to open at the junction upon application of electrical energy.

8. An integrated circuit fuse as defined in claim 1, wherein the junction has a width of about 0.5 micrometer or less.

9. An integrated circuit fuse as defined in claim 1, wherein the circuit connections comprise a connection to a supply voltage of the integrated circuit.

10. An integrated circuit fuse as defined in claim 1, wherein the circuit connections comprise electrical connections to the conductive layer on opposite sides of the junction.

11. An integrated circuit fuse as defined in claim 1, further comprising a shield above the junction.

12. A method for fabricating an integrated circuit fuse, comprising:
forming in a substrate P-type and N-type regions which abut at a junction;
forming a conductive layer on the P-type and N-type regions; and
connecting the conductive layer to an electrical energy source for applying sufficient electrical energy to open the conductive layer at the junction in response to a fuse program signal.

13. A method as defined in claim 12, wherein forming P-type and N-type regions comprises forming P-type and N-type diffusions, respectively.

14. A method as defined in claim 13, comprising forming P-type and N-type diffusions in an N-well in the substrate.

15. A method as defined in claim 12, wherein forming a conductive layer comprises forming a silicide layer.

16. A method as defined in claim 12, wherein forming a conductive layer comprises forming a metal layer.

17. A method as defined in claim 12, wherein forming a conductive layer comprises forming a tungsten layer.

18. A method as defined in claim 12, wherein forming a conductive layer comprises controlling a width and thickness of the conductive layer to provide desired fuse programming conditions.

19. A method as defined in claim 12, wherein forming a conductive layer comprises controlling a shape of the conductive layer to provide desired fuse programming conditions.

20. A method as defined in claim 12, wherein forming a conductive layer comprises patterning the conductive layer with a masking layer to provide desired fuse programming conditions.

21. A method as defined in claim 12, wherein forming a conductive layer comprises patterning the conductive layer to provide minimum width over the junction.

22. A method as defined in claim 12, wherein forming a conductive layer comprises patterning the conductive layer to enhance current density over the junction.

23. A method as defined in claim 12, wherein connecting the conductive layer comprises connecting the conductive layer to a supply voltage of the integrated circuit.

24. A method as defined in claim 12, wherein connecting the conductive layer comprises providing connections to the conductive layer and the P-type and N-type regions on opposite sides of the junction.

25. A method as defined in claim 12, further comprising forming a shield above the junction.

26. An integrated circuit fuse comprising:
P-type and N-type diffusions in an N-well formed in a substrate, said P-type and N-type diffusions abutting at a junction;
a silicide layer on the P-type and N-type diffusions; and
circuit connections to the silicide layer and to the P-type and N-type diffusions on opposite sides of the junction for applying sufficient electrical energy to open the silicide layer at the junction in response to a fuse program signal.
